(19) United States
(12) Patent Application Publication
(10) Pub. No.: US 2007/0221264 A1
(43) Pub. Date: Sep. 27, 2007

(54) THERMOELECTRIC CONVERSION MODULE AND METHOD OF MANUFACTURING THE SAME

(76) Inventors: Naoki SHUTOH, Yokohama-shi (JP); Hiromitsu TAKEDA, Tokyo (JP); Shinya SAKURADA, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/687,744

(22) Filed: Mar. 19, 2007

(30) Foreign Application Priority Data
Mar. 24, 2006 (JP) 2006-083366

(51) Int. Cl. H01L 35/28

(52) U.S. Cl. 136/224

(57) ABSTRACT

There is provided a thermoelectric conversion module comprising a first insulated substrate, a plurality of columnar p-type and n-type semiconductor thermoelectric transducers alternately arranged on the first insulated substrate, a second insulated substrate arranged so as to face the first insulation with interposition of the semiconductor thermoelectric transducers, first electrodes arranged between the first insulated substrate and the respective semiconductor thermoelectric transducers, and second electrodes arranged between the second insulated substrate and the respective semiconductor thermoelectric transducers, the first and second electrodes electrically connecting the p-type and n-type semiconductor thermoelectric transducers in series, and a glass film coated on the exposed surface of each first electrode at the first insulated substrate side and on a part of the exposed surfaces of the p-type and n-type semiconductor thermoelectric transducers directed from the first electrode to the second electrode.

### CROSS-REFERENCE TO RELATED APPLICATIONS

This application is based upon and claims the benefit of priority from prior Japanese Patent Application No. 2006-083366, filed Mar. 24, 2006, the entire contents of which are incorporated herein by reference.

### BACKGROUND OF THE INVENTION

1. Field of the Invention

The invention relates to a thermoelectric conversion module and a method of manufacturing the same.

2. Description of the Related Art

Since efficient use of energy is a crucial problem in the near future when exhaustion of natural resources is a worry, various systems have been devised. Among these systems, thermoelectric transducers that generate thermal electromotive force by taking advantage of the so-called Seebeck effect are expected as means for recovering energy that has been wastefully discharged in the environment in the system that affords a temperature difference. The thermoelectric transducers are used as a module in which p-type semiconductor thermoelectric transducers and n-type semiconductor thermoelectric transducers are alternately connected in series.

When one of the surfaces of an array of the p-type and n-type semiconductor thermoelectric transducers is placed on a high temperature side and the other surface is placed on a low temperature side, the magnitude of generated electrical energy (W) of the thermoelectric conversion module is proportional to a product of a thermoelectric conversion efficiency α and a temperature difference ΔT between the high temperature and the low temperature as shown by the following equation (1):

W∝α×ΔT (1)

Many semiconductor thermoelectric transducers have been hitherto studied for attaining high thermoelectric conversion efficiency, and an example of the practically used thermoelectric transducer having high thermoelectric conversion efficiency is bismuth (Bi)-tellurium (Te) systems (may contain Sb and selenium (Se) as a third element). However, while these materials have high thermoelectric conversion efficiency, it is difficult to efficiently recover the energy since thermoelectric performance is low at a temperature exceeding 250° C. More specifically, ΔT in equation (1) cannot be increased when thermoelectric performance at a high temperature is low. It is evident from equation (1) that a material capable of increasing ΔT three times is far more advantageous even when the thermoelectric conversion efficiency α is as low as 50% of the conventional thermoelectric conversion materials.

There are two problems of development for enhancing the operating temperature of the thermoelectric conversion member: one is an essential one whether the thermoelectric transducer is able to exhibit a desired performance, and the other is an adjunctive one in practical use. Oxidation of the thermoelectric transducer is crucial in the latter problem.

Semiconductor thermoelectric transducers of a half-Heusler base and a filled skutterudite base are considered to be promising as the thermoelectric transducers capable of being operated at high temperatures. Rare earth elements such as lanthanum (La), Cerium (Ce), yittrium (Y) and erbium (Er), and active metals such as hafnium (Hf), zirconium (Zr) and titanium (Ti) are added to these semiconductor thermoelectric transducers in order to improve the thermoelectric performance. However, use of these metals in a high temperature/highly oxidizing atmosphere is restricted since they have a quite high affinity with oxygen and are less resistant to oxidation.

Based on these results, JP-A 11-251647 (KOKAI) discloses a method which connects a p-type semiconductor thermoelectric transducer and an n-type semiconductor thermoelectric transducer with electrodes arranged on and under the thermoelectric transducers, and covers exposed surfaces (side faces) of these thermoelectric transducers with a glass film mainly comprising PbO and TeO₂ to prevent the semiconductor thermoelectric transducers from being oxidized.

However, in the method disclosed in JP-A 11-251647 (KOKAI), the upper and lower electrodes are connected to the glass film that covers the entire exposed surfaces (side faces). For this reason, heat also flows through the glass film other than the thermoelectric transducers to cause heat energy loss.

Meanwhile, a thermoelectric conversion module is configured such that p-type and n-type semiconductor thermoelectric transducers are alternately arranged and are connected in series through the electrodes. As a consequence, complicated and precise work is inevitable for assembling the members into a module. In particular, the step of alternately arranging the p-type and n-type semiconductor thermoelectric transducers is quite difficult as the density of arrangement of the semiconductor thermoelectric transducers is higher.

Alternatively, JP-A 2005-129765 (KOKAI) discloses a method of producing a thermoelectric conversion module having a structure in which p-type and n-type semiconductor thermoelectric transducers are arranged by inserting them into a frame having plural through holes (holes having openings at both ends), and electrodes are connected to both ends of each semiconductor thermoelectric transducer exposed from each hole of the frame such that the p-type and n-type semiconductor thermoelectric transducers are connected in series with one another. The electrodes are formed and supported on respective insulated substrates. It is possible in the method of manufacturing the thermoelectric conversion module to simply arrange the thermoelectric transducers with high density and high precision.

However, the electrodes of the insulated substrates are arranged on and under the p-type and n-type semiconductor thermoelectric transducers, respectively, and the frame is arranged between the insulated substrates in the method disclosed in JP-A 2005-129765 (KOKAI). Accordingly, heat flows through the frame other than the thermoelectric transducers, and causes larger energy loss as compared with the method of covering the side faces of the thermoelectric transducers with the glass film as disclosed in JP-A 11-251647 (KOKAI) described above.

### BRIEF SUMMARY OF THE INVENTION

According to a first aspect of the present invention, there is provided a thermoelectric conversion module comprising:

a first insulated substrate;

a plurality of columnar p-type and n-type semiconductor thermoelectric transducers alternately arranged on the first insulated substrate;

a second insulated substrate arranged so as to face the first insulated substrate with interposition of the semiconductor thermoelectric transducers;

first electrodes arranged between the first insulated substrate and the respective semiconductor thermoelectric transducers, and second electrodes arranged between the second insulated substrate and the respective semiconductor thermoelectric transducers, the first and second electrodes electrically connecting the p-type and n-type semiconductor thermoelectric transducers in series; and

a glass film which covers the exposed surface of each first electrode at the first insulated substrate side and a part of the exposed surfaces of the p-type and n-type semiconductor thermoelectric transducers directed from the first electrode to the second electrode.

According to a second aspect of the present invention, there is provided a method of manufacturing a thermoelectric conversion module, comprising:

preparing a frame containing a glass powder and an organic binder and having a plurality of through holes;

preparing a first insulated substrate having a plurality of first electrodes arrayed and fixed on one surface thereof, and a second insulated substrate having a plurality of second electrodes arrayed and fixed on one surface thereof;

alternately inserting a plurality of columnar p-type semiconductor thermoelectric transducers and a plurality of columnar n-type semiconductor thermoelectric transducers into the through holes of the frame to arrange the thermoelectric transducers;

putting the plurality of first electrodes of the first insulated substrate on one end surfaces of the adjoining p-type and n-type semiconductor thermoelectric transducers, and putting the plurality of second electrodes of the second insulated substrate on the other end surface of the adjoining p-type and n-type semiconductor thermoelectric transducers such that the first and second electrodes electrically connect the p-type and n-type semiconductor thermoelectric transducers in series with one another via a solder material at which the plurality of p-type and n-type semiconductor thermoelectric transducers are inserted into the through holes of the frame, thereby forming an assembly; and

heating the assembly to melt the solder material and the frame in the assembly, thereby applying molten frame to the exposed surfaces of the first electrodes at the first insulated substrate and to a part of the exposed surfaces of the p-type and n-type semiconductor thermoelectric transducers directed from the first electrode to the second electrode, and then solidifying molten frame and molten solder material, whereby solidifying solder material bonds the first and second electrodes to the respective end faces of the p-type and n-type semiconductor thermoelectric transducers.

### BRIEF DESCRIPTION OF THE SEVERAL VIEWS OF THE DRAWING

FIG. 1 is a perspective view showing a thermoelectric conversion module according to an embodiment of the invention;

FIG. 2 is a cross section taken along the line II-II in FIG. 1; and

FIG. 3 is an exploded perspective view for describing a method of manufacturing the thermoelectric conversion module according to the embodiment.

### DETAILED DESCRIPTION OF THE INVENTION

A thermoelectric conversion module according to an embodiment of the invention and a method of manufacturing the same will be described below with reference to the drawings.

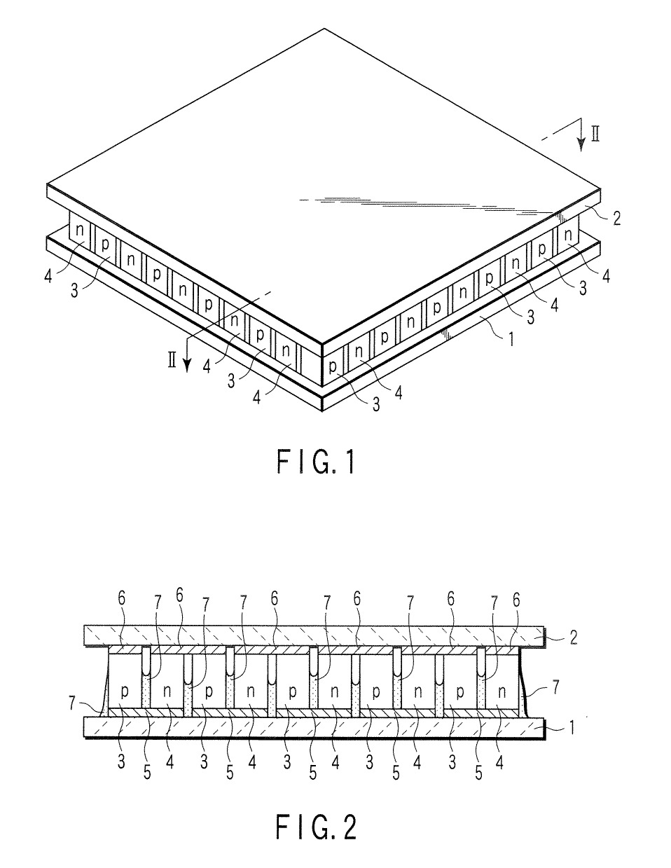

FIG. 1 is a perspective view showing the thermoelectric conversion module according the embodiment, and FIG. 2 is a cross section taken along the line II-II in FIG. 1.

First and second insulated substrate 1 and 2 are arranged so as to face to each other. The insulated substrate 1 and 2 are preferably made of ceramics substrate such as silicon nitride ceramics, aluminum nitride ceramics and aluminum oxide ceramics. Plural columnar p-type and n-type semiconductor thermoelectric transducers 3 and 4 (for example, square columns) are alternately arranged, for example as a checker, along the surface of the insulated substrate between the first and second insulated substrate 1 and 2. The shapes of the p-type and n-type semiconductor thermoelectric transducers 3 and 4 are not restricted to being square columns, and may be polygonal columns such as triangular and pentagonal columns, or round columns. The p-type and n-type semiconductor thermoelectric transducers 3 and 4 may be made of any one of a half-Heusler base material, a filled skutterudite base material and iron-silicide base material. The p-type and n-type semiconductor thermoelectric transducers 3 and 4 may be made of the same material or different materials selected from the above-mentioned materials. Among these materials, the half-Heusler base material has the highest thermoelectric performance while the iron-silicide base material has an excellent anti-oxidative property.

A plurality of first electrodes 5 made of, for example, copper, stainless steel or silver are arranged on the surface of the first insulated substrate 1 at the side where the plural p-type and n-type semiconductor thermoelectric transducers 3 and 4 are arranged. These first electrodes 5 are joined and connected to the end faces of the adjoining p-type and n-type semiconductor thermoelectric transducers 3 and 4, respectively, via an Ag-base active metal solder at the first insulated substrate 1 side. For example, a plurality of second electrodes 6 made of, for example, copper, stainless steel or silver are arranged on the surface of the second insulated substrate 2 at the side where the plural p-type and n-type semiconductor thermoelectric transducers are arranged. These second electrodes 6 are joined and connected to the end faces of the adjoining p-type and n-type semiconductor thermoelectric transducers 3 and 4, respectively, via the Ag-base active metal solder at the second insulated substrate 2 side. The p-type and n-type semiconductor thermoelectric transducers 3 and 4 are electrically connected in series with one another through the first and second electrodes 5 and 6, respectively.

Glass films 7 are coated on the exposed surface of the first electrode 5 at the first insulated substrate 1 side and on a part of the exposed surfaces of the p-type and n-type semiconductor thermoelectric transducers 3 and 4 directed from the first electrode 5 to the second electrode 6.

The phrase “a part of the exposed surfaces of the semiconductor thermoelectric transducers 3 and 4” as used herein refers to 90% or less, preferably 80% or less, of the length of the columnar semiconductor thermoelectric transducers 3 and 4. The glass film may be also coated on the exposed surface of the second electrode 6 at the second insulated substrate 2 side and the exposed surfaces of the semiconductor thermoelectric transducers 3 and 4 in the vicinity thereof.

When the first insulated substrate 1 side having the first electrode 5 is placed at a higher temperature side and the second insulation electrode 2 side having the second electrode 6 is placed at a lower temperature side for generating an electric energy using the thermoelectric conversion module according to the embodiment, the glass film 7 is preferably coated on the exposed surface of the first electrode 5 at the first insulated substrate 1 side.

The glass film 7 is preferably selected from materials having a difference of a thermal expansion coefficient within ±15% from the thermal expansion coefficient of the semiconductor thermoelectric transducers 3 and 4. Examples of the glass having such a thermal expansion coefficient include a lead-free borosilicate zinc glass having a composition comprising 40 to 50% by weight of SiO₂, 15 to 20% by weight of ZnO, 10 to 15% by weight of B₂O₃, 5 to 10% by weight of BaO, 15 to 20% by weight of K₂O and 1 to 5% by weight of Al₂O₃.

According to the structure shown in FIGS. 1 and 2, the first insulated substrate 1 is arranged at the higher temperature side while the second insulated substrate 2 is arranged at the lower temperature side. Thereby, the plural p-type and n-type semiconductor thermoelectric transducers 3 and 4 of a square column shape are arranged between the first insulated substrate 1 and the second insulated substrate 2, and are connected in series with the first electrode 5 on the first insulated substrate 1 and the second electrode 6 on the second insulated substrate 2, respectively. Consequently, electrical energy is generated according to the above equation (1) depending on the generated temperature difference and intrinsic thermoelectric conversion efficiency of each of the thermoelectric transducers 3 and 4.

When the electrical energy is generated by the thermoelectric conversion module, the semiconductor thermoelectric transducers 3 and 4, particularly the portions thereof in the vicinity of the first insulated substrate 1 exposed to a higher temperature side, are degraded by oxidation, since the p-type and n-type semiconductor thermoelectric transducers 3 and 4 made of the filled skutterudite or half-Heusler contain rare earth elements and active metals having high affinity with oxygen.

As shown in FIG. 2, the exposed surface of the first electrode 5 at the first insulated substrate 1 side exposed at the high temperature side is coated with the glass film 7, and the exposed surfaces of the p-type and n-type semiconductor thermoelectric transducers 3 and 4 directing from the first electrode 5 to the second electrode 6 are coated with the glass film 7 until halfway thereof in the thermoelectric conversion modules. Consequently, the semiconductor thermoelectric transducers 3 and 4 are prevented from being oxidized in a high temperature atmosphere.

Since the coating region of the glass film 7 is until the halfway of the exposed surfaces of the semiconductor thermoelectric transducers 3 and 4 directing from the first electrode 5 to the second electrode 6, the heat flows only into the semiconductor thermoelectric transducers 3 and 4 without flowing into the glass film 7. Accordingly, efficient generation of electrical energy is possible by preventing energy loss.

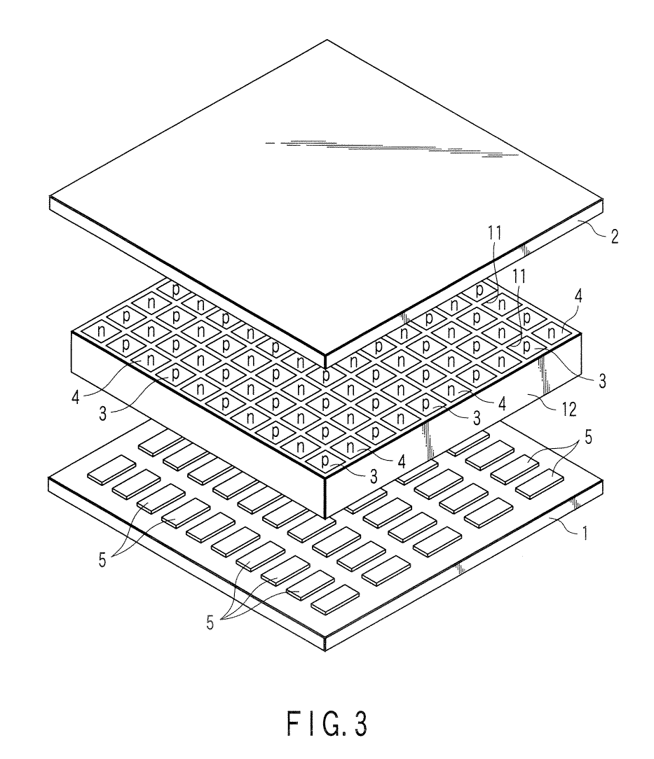

The method of manufacturing the thermoelectric conversion module according to the embodiment will be described below with reference to FIG. 3.

First, a frame 12 is prepared which contains a glass powder and an organic binder and has a plurality of through holes (for example, square columnar through holes) 11. A first insulated substrate 1 on which plural first electrodes 5 made of, for example, copper, stainless steel or silver have been arranged and fixed on one surface, and a second insulated substrate 2 on which plural second electrodes (not shown) made of, for example, copper, stainless steel or silver have been arranged and fixed on one surface are also prepared.

Then, a plurality of p-type columnar (for example, square columnar) semiconductor thermoelectric transducers 3, and a plurality of n-type columnar (for example, square columnar) semiconductor thermoelectric transducers 4 are inserted into the through holes 11 of the frame 12 such that the n-type and p-type thermoelectric transducers 3 and 4 are alternately arranged (for example as a checker). Subsequently, one of the plural first electrodes 5 on the first insulated substrate 1 and one of the plural second electrodes (not shown) on the second insulated substrate 2 are put on the surfaces of one end and the other end, respectively, of adjoining p-type and n-type semiconductor thermoelectric transducers 3 and 4, which belong to the plural p-type and n-type semiconductor thermoelectric transducers 3 and 4 inserted into the through holes 11 of the frame 12, via an Ag-base active metal solder. The end faces of the p-type and n-type semiconductor thermoelectric transducers 3 and 4 are put on the respective first and second electrodes as follows. That is, by bonding with the active metal solder by heating and solidifying as will be described below, the p-type and n-type semiconductor thermoelectric transducers 3 and 4 are electrically connected in series to one another through the first electrode 5 and second electrode (not shown). An assembly which comprises: the frame 12 into which the plural p-type and n-type semiconductor thermoelectric transducers 3 and 4 have been inserted; the first insulated substrate 1 located at the lower side and having the first electrodes 5; and the second insulated substrate 2 located at the upper side and having the second electrodes (not shown) is formed by above process.

The assembly is heated to melt the Ag-base active metal solder and the frame 12 containing the glass powder and organic binder. At this time, a molten substance (molten glass) is produced by melting the frame 12. The molten glass is coated the exposed surfaces of the first electrodes 5 at the first insulated substrate 1 and a part of the exposed surfaces of the p-type and n-type semiconductor thermoelectric materials 3 and 4 directed from the first electrode 5 to the second electrode 6, then the molten glass is solidified. Simultaneously, the molten Ag-base active metal solder is solidified, whereby solidifying Ag-base active metal solder bonds the first and second electrodes 5 and 6 to the respective end faces of the p-type and n-type semiconductor the thermoelectric transducers 3 and 4. Therefore, a thermoelectric conversion module is manufactured by coating the exposed surfaces of the first electrode 5 at the first insulated substrate 1 side and a part of the exposed surfaces of the p-type and n-type semiconductor thermoelectric transducer 3 and 4 directing from the first electrode 5 to the second electrode 6 with the glass film 7 as shown in FIG. 2.

The glass powder preferably has a difference of the thermal expansion coefficient within ±15% from the thermal expansion coefficient of the semiconductor thermoelectric transducers 3 and 4. Examples of the glass include a lead-free borosilicate zinc glass having a composition comprising 40 to 50% by weight of SiO₂, 15 to 20% by weight of ZnO, 10 to 15% by weight of B₂O₃, 5 to 10% by weight of BaO, 15 to 20% by weight of K₂O and 1 to 5% by weight of Al₂O₃. The glass powder preferably has an average particle diameter in the range from 5 to 200 μm.

Examples of the organic binder available include polyvinyl alcohol (PVA) and paraffin.

The assembly is preferably heated at a temperature in the range from 500 to 800° C. when the lead-free borosilicate zinc glass having the above-mentioned composition is used as the glass in the frame, although the temperature depends on the kind of the glass powder used.

According to the method of the embodiment, the plural p-type and n-type semiconductor thermoelectric transducers 3 and 4 are inserted into the plural through holes (for example, square columnar through holes) 11 of the frame 12, whereby the semiconductor thermoelectric transducers 3 and 4 can be simply arranged in high density with high precision. The first electrode 5 of the first insulated substrate 1 and the second electrode (not shown) of the second insulated substrate 2 is put on both end surfaces, respectively, of the adjoining p-type and n-type semiconductor thermoelectric transducers 3 and 4 via the Ag base active metal solder such that the adjoining materials are electrically connected to one another in series, thereby forming an assembly. Thereafter, the p-type and n-type semiconductor thermoelectric transducers 3 and 4 coated with the glass film 7 and the first electrode 5 and second electrode (not shown) are simultaneously bonded to end faces, respectively, of the thermoelectric transducers 3 and 4 by heating and solidifying Ag base active metal solder and the frame in the assembly, respectively, as shown in FIG. 2. Accordingly, the semiconductor thermoelectric transducers 3 and 4 are protected from being degraded by oxidation in a high temperature atmosphere.

Consequently, a thermoelectric conversion module having long term reliability can be readily produced by precisely arranging the p-type and n-type semiconductor thermoelectric transducers 3 and 4 at high density.

While the p-type and n-type semiconductor thermoelectric transducers 3 and 4 are arranged in two dimensions (for example, as a checker) in the embodiment, they may be aligned in one direction.

Examples of the invention will be described in detail hereinafter.

### EXAMPLE 1

A paste was prepared by mixing a lead-free glass powder (trade name: JV-35, manufactured by Matstunami Glass Industry Ltd.) in a solution comprising 5% by weight of polyvinyl alcohol (PVA) dissolved in dimethylsulfoxide (DMSO). Then, the paste was extruded with a die and dried to obtain a honeycomb frame having 10×10 square through holes. Subsequently, 50 square columns each of p-type and n-type half-Heusler thermoelectric transducers (100 columns in total) were inserted into the through holes of the honeycomb frame such that p-type and n-type thermoelectric transducers were arranged as a checker to one another. (Ti_{0.3}Zr_{0.35}Hf_{0.35})—CoSb_{0.85}Sn_{0.15} was used as the p-type thermoelectric conversion material, and (Ti_{0.3}Zr_{0.35}Hf_{0.35})—NiSn_{0.994}Sb_{0.006} was used as the n-type thermoelectric conversion material.

Then, the honeycomb frame having the thermoelectric transducers inserted therein was sandwiched between first and second insulated substrates made of silicon nitride ceramics and having first and second copper electrodes for forming a desired series circuit, thereby forming an assembly. A paste of silver-base active metal solder containing Ti had been coated on the first and second electrodes in advance. Subsequently, the assembly was heated at 830° C. in an argon atmosphere while the first insulated substrate was placed downside and the second insulated substrate was placed upside. Silver-base active metal solder containing Ti in the paste was melted, then solidifying, whereby the first and second electrodes were bonded to the end faces of the respective thermoelectric transducers with solidifying the silver-base active metal solder containing Ti. The honeycomb frame is simultaneously melted by heating to coat with the molten glass the exposed surface of the first electrode at the first insulated substrate side located at the lower side and a part of the exposed surfaces of the p-type and n-type semiconductor thermoelectric transducers, i.e., a length of ⅗ of the length from the lower side of the thermoelectric transducer directed from the first electrode to the second electrode. Then, the molten glass is solidified described above, thereby manufacturing a thermoelectric conversion module.

The thermoelectric conversion module obtained was attached to a thermoelectric performance evaluation apparatus capable of affording a large temperature difference, where the first insulated substrate was placed on a heating side and the second insulated substrate was placed on a cooling side. The temperature of the second insulated substrate (cooling side) was controlled at 100° C. while the first insulated substrate (heating side) was heated at 800° C. in 30 minutes. The temperature was kept for 5 hours, and a cycle of cooling to 100° C. in 60 minutes was repeated. The module was electrically connected to a load resistance, and the amount of the generated electric energy was measured while adding the cycle of heating.

The results showed that no decrease of the generated electrical energy was observed even after 500 cycles, and the module was confirmed to have long term reliability.

### COMPARATIVE EXAMPLE 1

Square columnar p-type and n-type half-Heusler thermoelectric transducers (50 transducers each, 100 members in total) were arranged on a first insulated substrate made of silicone nitride ceramics and having first copper electrodes for forming a desired series circuit without using any honeycomb frame such that the p-type and n-type thermoelectric transducers were aligned as a checker. A second insulated substrate made of silicone nitride ceramics and having second electrodes for forming the desired series circuit was placed at the upper ends of these thermoelectric transducers. The first and second electrodes had been coated with a silver-base active metal solder paste with Ti in advance. Then, silver-base active metal solder in the paste was melted by heating at 830° C. in an argon atmosphere, and then solidifying the molten silver solder, whereby the first and second electrodes were bonded to respective end faces of the thermoelectric transducers with solidifying silver solder containing Ti. As result, a thermoelectric conversion module was manufactured.

The thermoelectric conversion module obtained was subjected to the same heat load test as in Example 1. As a result, the amount of the generated electric energy started to decrease at the second cycle, and the module was degraded to such an extent that almost no generation of electrical energy could be detected at the fifth cycle and thereafter. The thermoelectric conversion module was visually observed after the fifth cycle, and it was found that the high temperature side of each thermoelectric transducer is severely oxidized with significant oxidation of the first electrode.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A thermoelectric conversion module comprising:
a first insulated substrate;
plural columnar p-type and n-type semiconductor thermoelectric transducers alternately arranged on the first insulated substrate;
a second insulated substrate arranged so as to face the first insulated substrate with interposition of the semiconductor thermoelectric transducers;
first electrodes arranged between the first insulated substrate and the respective semiconductor thermoelectric transducers, and second electrodes arranged between the second insulated substrate and the respective semiconductor thermoelectric transducers, the first and second electrodes electrically connecting the p-type and n-type semiconductor thermoelectric transducers in series; and
a glass film which covers the exposed surface of each first electrode at the first insulated substrate side and a part of the exposed surfaces of the p-type and n-type semiconductor thermoelectric transducers directed from the first electrode to the second electrode.

2. The thermoelectric conversion module according to claim 1, wherein the first and second insulated substrates are made of silicon nitride ceramics or aluminum nitride ceramics.

3. The thermoelectric conversion module according to claim 1, wherein at least one of the p-type and n-type semiconductor thermoelectric transducers is made of a filled skutterudite base material.

4. The thermoelectric conversion module according to claim 1, wherein at least one of the p-type and n-type semiconductor thermoelectric transducers is made of a half-Heusler base material.

5. The thermoelectric conversion module according to claim 1, wherein at least one of the p-type and n-type semiconductor thermoelectric transducers is made of an iron-silicide base material.

6. The thermoelectric conversion module according to claim 1, wherein the glass is a lead-free glass.

7. The thermoelectric conversion module according to claim 1, wherein the glass film has a difference of a thermal expansion coefficient of within ±15% from the thermal expansion coefficient of the semiconductor thermoelectric conversion member.

8. The thermoelectric conversion module according to claim 1, wherein the glass is a lead-free borosilicate zinc glass having a composition comprising 40 to 50% by weight of SiO₂, 15 to 20% by weight of ZnO, 10 to 15% by weight of B₂O₃, 5 to 10% by weight of BaO, 15 to 20% by weight of K₂O and 1 to 5% by weight of Al₂O₃.

9. The thermoelectric conversion module according to claim 1, wherein a part of the exposed surface of the semiconductor thermoelectric transducer coated with the glass film is 90% or less of the length of the columnar semiconductor thermoelectric transducers.

10. The thermoelectric conversion module according to claim 1, wherein a part of the exposed surface of the semiconductor thermoelectric transducer coated with the glass film is 80% or less of the length of the columnar semiconductor thermoelectric transducer.

11. The thermoelectric conversion module according to claim 1, wherein, when the exposed surface of the first electrode on the first insulated substrate is coated with the glass film, electric energy is generated by placing the first insulated substrate at a high temperature side.

12. A method of manufacturing a thermoelectric conversion module, comprising:
preparing a frame containing a glass powder and an organic binder and having a plurality of through holes;
preparing a first insulated substrate having a plurality of first electrodes arrayed and fixed on one surface thereof, and a second insulated substrate having a plurality of second electrodes arrayed and fixed on one surface thereof;
alternately inserting a plurality of columnar p-type semiconductor thermoelectric transducers and a plurality of columnar n-type semiconductor thermoelectric transducers into the through holes of the frame to arrange the thermoelectric transducers;
putting the plurality of first electrodes of the first insulated substrate on one end surfaces of the adjoining p-type and n-type semiconductor thermoelectric transducers, and putting the plurality of second electrodes of the second insulated substrate on the other end surface of the adjoining p-type and n-type semiconductor thermoelectric transducers such that the first and second electrodes electrically connect the p-type and n-type semiconductor thermoelectric transducers in series with one another via a solder material at which the plurality of p-type and n-type semiconductor thermoelectric transducers are inserted into the through holes of the frame, thereby forming an assembly; and
heating the assembly to melt the solder material and the frame in the assembly, thereby applying molten frame to the exposed surfaces of the first electrodes at the first insulated substrate and to a part of the exposed surfaces of the p-type and n-type semiconductor thermoelectric transducers directed from the first electrode to the second electrode, and then solidifying molten frame and molten solder material, whereby solidifying solder material bonds the first and second electrodes to the respective end faces of the p-type and n-type semiconductor thermoelectric transducers.

13. The method according to claim 12, wherein the glass powder is a lead-free borosilicate zinc glass powder having a composition comprising 40 to 50% by weight of SiO₂, 15 to 20% by weight of ZnO, 10 to 15% by weight of B₂O₃, 5 to 10% by weight of BaO, 15 to 20% by weight of K₂O and 1 to 5% by weight of Al₂O₃.

14. The method according to claim 12, wherein the organic binder is polyvinyl alcohol or paraffin.

15. The method according to claim 13, wherein the assembly is heated at a temperature in the range from 500 to 800° C.

16. The method according to claim 12 wherein at least one of the p-type and n-type semiconductor thermoelectric transducers is made of a filled skutterudite base material.

17. The method according to claim 12 wherein at least one of the p-type and n-type semiconductor thermoelectric transducers is made of a half-Heusler base material.

18. The method according to claim 12 wherein at least one of the p-type and n-type semiconductor thermoelectric transducers is made of an iron-silicide base material.

19. The method according to claim 12 wherein the first and second insulated substrates are made of silicon nitride ceramics or aluminum nitride ceramics.
